(19) United States
(12) Patent Application Publication
(10) Pub. No.: US 2011/0316556 A1
(43) Pub. Date: Dec. 29, 2011

(54) CALIBRATING A CHANNEL OF A TEST SYSTEM

(76) Inventors: Eric Paul Bergeron, Melrose, MA (US); Damain John Megna, Framingham, MA (US); John Anson Whealler, Cohasset, MA (US)

(21) Appl. No.: 12/826,063

(22) Filed: Jun. 29, 2010

(51) Int. Cl. G01R 35/00; G01R 29/00

(52) U.S. Cl. 324/601; 324/76.11; 324/105

(57) ABSTRACT

Circuitry includes a circuit path that corresponds to a channel of system for testing a device, an element in the circuit path, a first device to measure an electrical parameter associated with the element, a second device to obtain an error signal associated with the channel, and a feedback path electrically connected to the second device to pass the error signal or another signal.

### TECHNICAL FIELD

This patent application relates generally to calibrating a channel of a test system.

### BACKGROUND

In a test system, periodic calibration of test channels is performed in order to ensure that the test channels meet their target specifications. A contributor to error in the test channels between calibrations is temperature change. This includes, but is not limited to, both ambient temperature shifts and local heating due to hot spots/components within a test channel and neighboring test channels. In this regard, a channel board (i.e., a circuit board on which test channels reside) may be air cooled. Good layout practices can sometimes ensure that sensitive circuits are not significantly affected by air that has been heated by hot spots on the board. However, with higher channel densities, and random heat dissipations in each channel, good layout practices may not completely eliminate errors caused by heating. Common mode voltage variations may also cause errors in the test channel.

### SUMMARY

This patent application describes calibrating a channel of a test system.

Described herein is circuitry that includes a circuit path that corresponds to a channel of system for testing a device, an element in the circuit path, a first device to measure an electrical parameter associated with the element, a second device to obtain an error signal associated with the channel, and a feedback path electrically connected to the second device to pass the error signal or another signal. The circuitry may comprise one or more of the following features, either alone in combination.

The second device may be configurable for operation in different modes. In a first of the modes, the second device may be configured to obtain the error signal, and, in a second of the modes, the second device may be configured to measure the electrical parameter. The feedback path may be configured to pass the other signal, where the other signal corresponds to the electrical parameter. Configuration of the second device may be performed by controlling switches electrically connected to inputs of the second device.

The circuitry may further comprise a controller to receive the error signal and to adjust an amount of current output to the current path in accordance with the error signal. The error signal may correspond to a variation in voltage caused by thermal drift and variations in common mode voltage in the channel.

The first device may comprise input terminals, with an input terminal electrically connected at each end of the element. The second device may comprise input terminals. The circuitry may comprise at least one switch. The at least one switch may comprise a first switch between a first input terminal of the second device and a first end of the element, and a second switch between a second input terminal of the second device and the first input terminal of the second device.

The circuitry may comprise control circuitry to control the first switch to open, thereby disconnecting the first input terminal from the first end of the electrical element, and to control the second switch to close, thereby electrically connecting the first input terminal to the second input terminal. The second input terminal may be electrically connected to a second end of the element.

A second feedback path may be electrically connected to the first device for compensating the input signal based on the electrical parameter measured at the first device. The first device may comprise a differential amplifier connected across the element, and the second device may comprise a differential amplifier comprising inputs that are electrically connectable to each other and that are electrically connectable across the element. The element may comprise a resistor and the electrical parameter may comprise a voltage associated with a current through the resistor. The second device may be configured to generate an analog signal that corresponds to the electrical parameter associated with the element. The circuitry may comprise a controller to produce a digital signal, and an analog-to-digital converter to produce a digitized version of the analog signal. The digitized version of the analog signal may be provided to the controller. The controller may be configured to alter the digital signal in accordance with the digitized version of the analog signal. The device under test may comprise a battery.

Also described herein is circuitry for use in a system comprised of bays for testing devices. The circuitry comprises a circuit path to pass a test signal, a calibration tote electrically connected to the circuit path, and a measurement device to determine an electrical parameter associated with the calibration tote in response to the test signal The calibration tote may be usable without interrupting testing of devices in other bays of the system. The circuitry may comprise one or more of the following features, either alone in combination.

The circuitry may comprise an apparatus configured to alter the test signal based on the electrical parameter. The apparatus may comprise a digital signal processor (DSP) that is configured to generate a digital signal that corresponds to the test signal, where the DSP is configured to alter the digital signal to alter the test signal. The calibration tote may comprise a resistor in series with a Zener diode, and the electrical parameter may comprise a voltage measured at least across the resistor. The calibration tote may be movable among bays in the system. The devices under test may comprise batteries.

Also described herein is a method of calibrating a channel of a device test system during operation of the device test system. The method comprises measuring an electrical parameter across a circuit element in the channel, applying a value corresponding to the electrical parameter to a signal input to the channel, and obtaining an error signal associated with the channel, the electrical parameter being measured by a first device and the error signal being measured by a second device. The method may comprise one or more of the following features, either alone in combination.

The method may comprise using the error signal to adjust the signal input to the channel. Using the error to adjust the signal input to the channel may comprise programming a controller to alter the signal in accordance with the error signal. The signal may be adjusted in real-time during testing of a device by the device test system. Obtaining the error signal may comprise electrically disconnecting a first terminal of the second device from a circuit path corresponding to the channel and electrically connecting first and second terminals of the second device to each other. Electrically disconnecting and electrically connecting may be performed by electrically-controllable switches. The channel of the device test system may be part of a bay of a test rack. The method may further comprise calibrating all channels of the bay using a calibration tote.

Also described herein is a method of calibrating a bay of a test system. The method comprises moving a calibration tote into the bay, and performing calibration on the bay using the calibration tote, the calibration being performed without interrupting processes being performed on devices in other bays. The method may comprise one or more of the following features, either alone in combination.

The calibration tote may comprise a resistor. Performing calibration may comprise obtaining an electrical parameter by measuring a value associated with the resistor, and/or determining a calibration factor for the bay using the value associated with the resistor.

Any two or more of the features described in this patent application, including this summary section, may be combined to form embodiments not specifically described in this patent application.

The details of one or more examples are set forth in the accompanying drawings and the description below. Further features, aspects, and advantages will become apparent from the description, the drawings, and the claims.

### DESCRIPTION OF THE DRAWINGS

FIGS. 1 to 3 show the same circuitry for calibrating a test channel, but configured differently in each of the figures.

FIG. 4 shows a circuit diagram that depicts an implementation of the circuitry shown in FIGS. 1 to 3.

FIG. 5 is a flowchart showing a process for calibrating a test channel.

FIG. 6 is a perspective view of a battery test system.

FIG. 7 shows a circuit diagram of a calibration tote.

FIG. 8 shows the circuit diagram of FIG. 4 with a connected calibration tote.

### DETAILED DESCRIPTION

Described herein is a method of calibrating a channel of a test system (e.g., for storage cells) during operation of the test system. The method includes measuring an electrical parameter across a circuit element in the channel, applying a value corresponding to the electrical parameter to a signal input to the channel, and obtaining an error signal associated with the channel. The electrical parameter is measured by a first device and the error is measured by a second device.

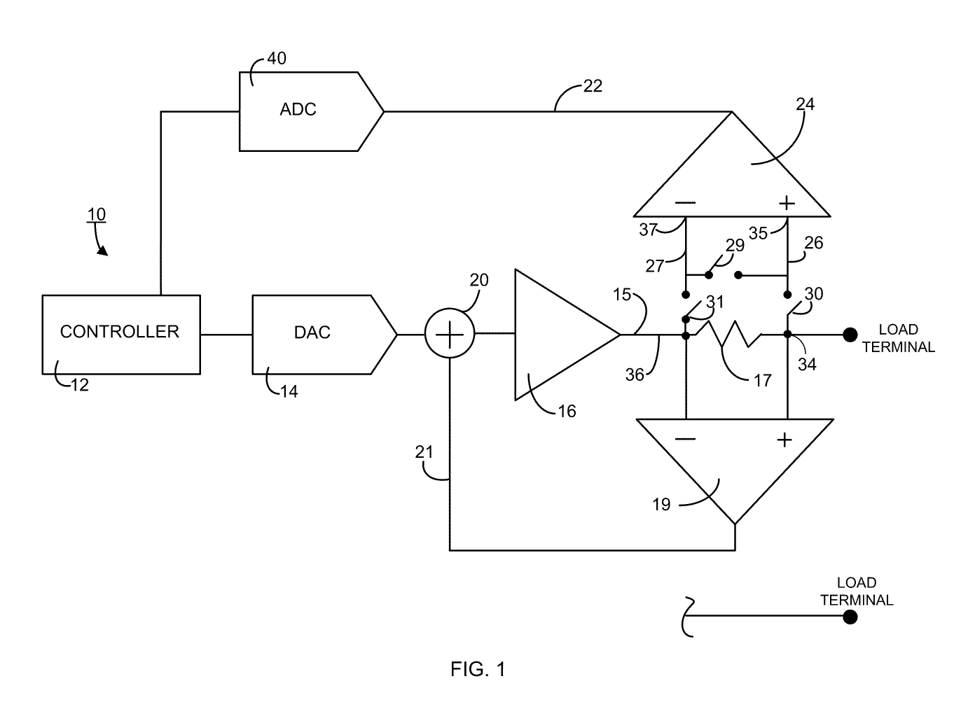

FIG. 1 shows a circuit 10 that is part of a channel of a test system, and that may be used to implement the foregoing method. In this example, the test system is for testing lithium ion batteries; however, circuit 10 may be incorporated into any type of test system.

Circuit 10 includes a controller 12. Controller 12 is a programmable digital controller in this implementation. For example, controller 12 may include/be, but is not limited to, a microprocessor, a digital signal processor (DSP) and/or programmable logic. Controller 12 may function as a current source in that it controls the amount of current output to the channel. By way of example, a digital-to-analog converter (DAC) 14 receives a digital signal from controller 12, which corresponds to an amount of output current. DAC 14 converts that digital signal into analog current. The analog current is output along circuit path 15, through which it passes to a battery or other device (not shown) under test.

Circuit path 15 may include an amplifier 16 or other circuitry, as shown in FIG. 1. Circuit path 15 also includes a circuit element, in this example, resistor 17. A differential amplifier 19 is electrically connected at each end of resistor 17 to measure a voltage across resistor 17, and to output a voltage. This voltage is fed back to summing junction 20 via feedback path 21. The summing junction subtracts this voltage from the voltage output by the DAC. If the difference is zero, an integrator in the summing junction outputs a current that is substantially constant (the integration of zero is a constant). If the difference is not zero, then the current output is altered to regulate the current through circuit path 15.

Circuit 10 includes a second feedback path 22. This second feedback path also includes a differential amplifier 24, which may be electrically connected at each end of resistor 17, as shown in FIG. 1. In an implementation, differential amplifier 24 has a higher accuracy than differential amplifier 19. Thus, differential amplifier 24 may be more sensitive to thermal (or other) environmental variations, such as thermal drift, and to variations in a common mode voltage of circuit path 15. However, this need not be the case, i.e., both differential amplifiers 19 and 24 may have similar, or substantially the same, responses to thermal and common mode variations. For example, both differential amplifiers may be the same or substantially similar type or be designed to have similar responses.

As shown in FIG. 1, the input terminals 26, 27 of differential amplifier 24 include switches 29, 30, 31. These switches enable the input terminal(s) of differential amplifier to connect to, or disconnect from, circuit path 15. In this implementation, the switches include switch 29, which, is between input terminals 26 and 27. When closed, switch 29 electrically connects (e.g., shorts) input terminals 26 and 27. Switch 30 is between point 34 on circuit path 15 and input 35 to differential amplifier 24; and switch 31 is between point 36 on circuit path 15 and input 37 to differential amplifier 24. When closed, switch 30 electrically connects differential amplifier input 35 to circuit path 15; and when closed, switch 31 electrically connects differential amplifier input 37 to circuit path 15.

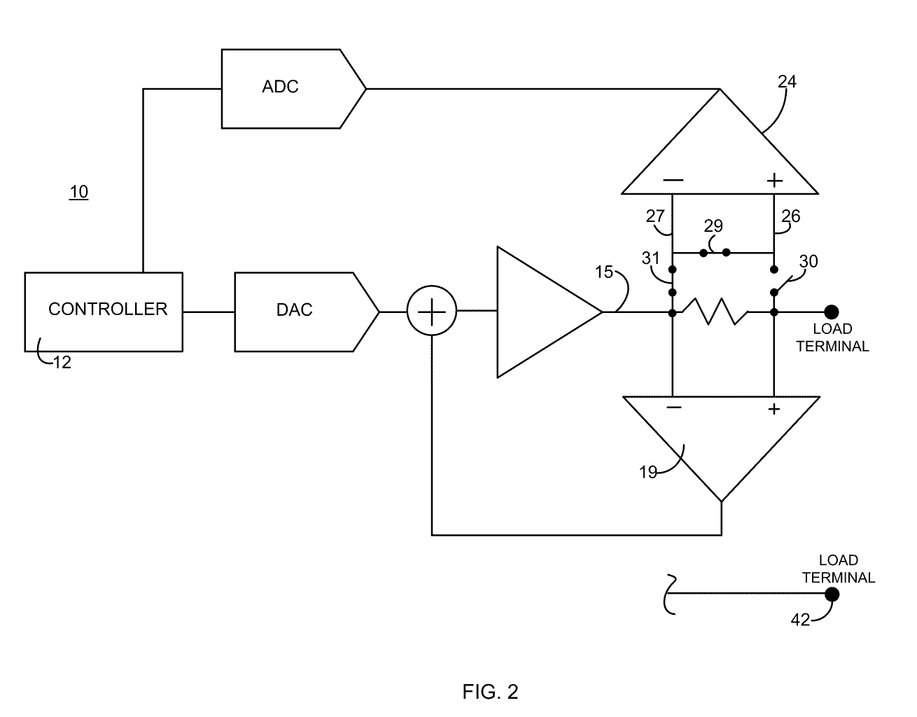

Switches 29, 30, 31 are controlled by a microprocessor or other processing device (not shown) that may be configured to control battery testing. For example, the switches may be configured as shown in FIG. 2. In FIG. 2, switch 30 is open thereby disconnecting input terminal 26 from circuit path 15, switch 31 is closed thereby electrically connecting input terminal 27 to circuit path 15, and switch 29 is closed thereby electrically connecting input terminals 26 and 27. Switch 31 may be replaced by a closed circuit.

In FIG. 2, the voltage measured by differential amplifier 24 should be zero (since terminals 26 and 27 are electrically connected, e.g., shorted). However, variations in temperature (and/or, possibly, other environmental conditions) and common mode voltage on path 15 can have an effect on differential amplifier 24 such that it does not output the correct voltage (in this case, zero). Rather, in this case, differential amplifier 24 outputs a voltage measured between input terminals 26 and 27. Since there should be no voltage between the input terminals (because they are electrically connected via switch 29), the output voltage represents an error introduced into differential amplifier, e.g., by temperature variations and common mode voltage variations in path 15.

The error signal (which corresponds to the voltage output) passes out of differential amplifier 24, along feedback path 22. Feedback path 22 is electrically connected between controller 12 and differential amplifier 24. Feedback path 22 includes an analog-to-digital (ADC) converter 40, which converts the analog voltage output of differential amplifier 24 to a digital signal. This digital signal corresponds to an error introduced by temperature variations (and, possibly, other environmental conditions) and common mode voltage variations. The error signal may be used by the controller to adjust the input current to the circuit to compensate for the error signal. More specifically, the error may be provided to a user (e.g., via controller 12 and a graphical user interface (GUI)), thereby enabling the user to identify/determine an amount of “error”. The user may direct the test equipment to use to error to adjust the programming of the controller to compensate for the thermal and common mode variations in differential amplifier 19. However, there is no requirement that error signal be used for correction in this manner. The error signal may simply be an informational aspect of the testing procedure.

In a case where the error signal is used for correction, the correction produced by the error signal may also constitute a correction for differential amplifier 19. The calibration using this correction may be performed in real-time, e.g., during operation of circuit 10, thereby increasing the accuracy of circuit 10.

In one example, the value of the error signal should be close to zero. Octant field-programmable gate arrays (FPGAs) associated with the test channel may store values output by the ADC and adjust the next output ADC code to the controller by an amount that corresponds to the error signal. These values may then be used to generate the current output to circuit path 15. A state machine may be used to handle connections of the switches and information storage. This circuitry may be used for all implementations described herein.

The output of differential amplifier 24 may be used to correct measurement instruments as well. For example, in FIG. 2, if the voltage output of differential amplifier should be zero, and a measurement instrument indicates otherwise; the voltage output may be used to provide a correction for the measurement instrument.

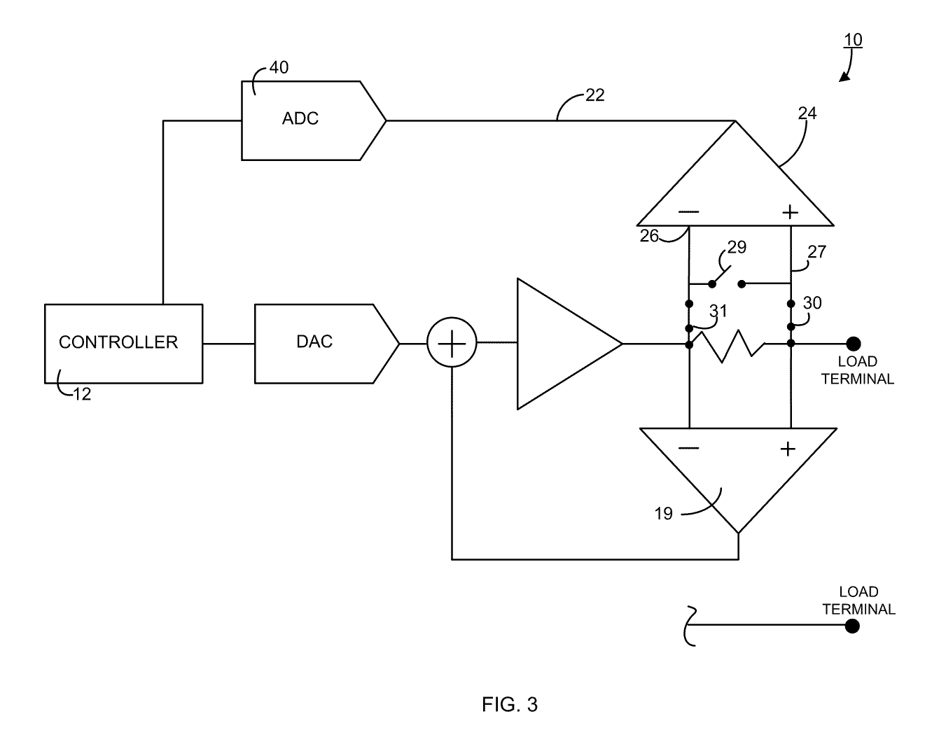

Referring to FIG. 3, switches 30 and 31 are controlled by a microprocessor or other processing device (not shown) to be closed, and switch 29 is controlled to be open. In this configuration, differential amplifier 24 behaves in a manner that is similar to differential amplifier 19. That is, differential amplifier 24 is electrically connected at each end of resistor 17 to measure a voltage across resistor 17, and to output a current that corresponds to that voltage. In this configuration, differential amplifier 24 is used simply to monitor the channel current through resistor 17, and to output a digital signal (e.g., via a GUI) to the user for display. This digital signal may be used to adjust current in the channel or it may simply be informational.

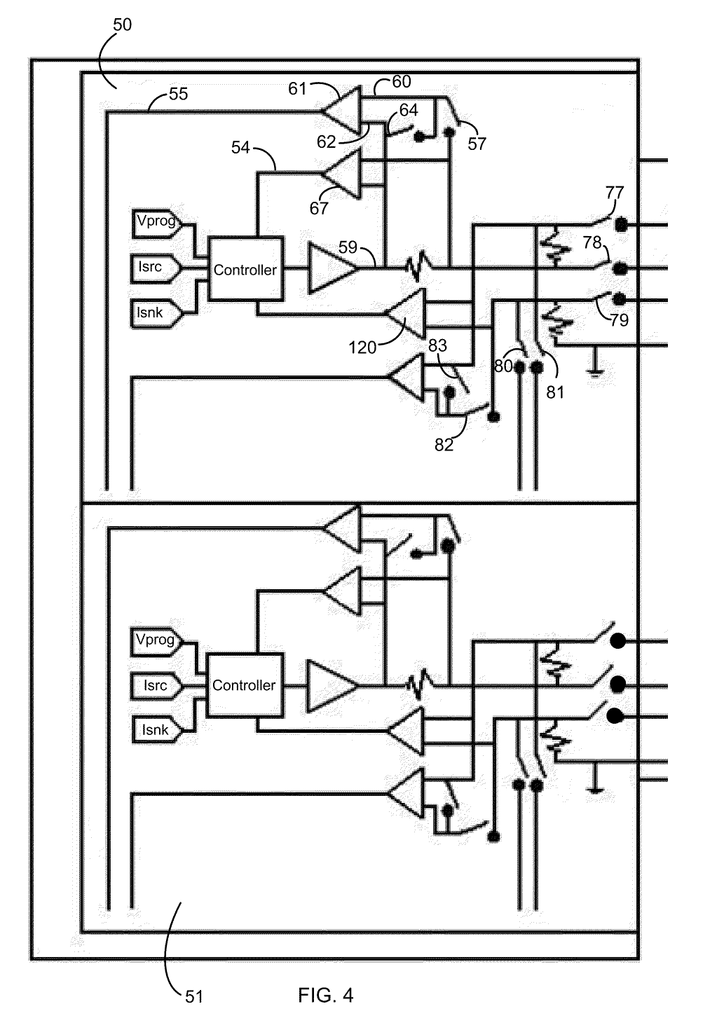

FIG. 4 shows an implementation of circuit 10, which includes two switches instead of the three shown in FIGS. 1 to 3. In FIG. 4, block 50 represents a first eight channels of a battery test system and block 51 represents a next second eight channels of that system. A substantially identical implementation of the circuit shown in FIGS. 1 to 3 is present in both blocks 50 and 51. Therefore, only one such circuit is described here.

Referring to FIG. 4, feedback path 21 of FIG. 1 corresponds to feedback path 54 of FIG. 4, and feedback path 22 of FIG. 1 corresponds to feedback path 55 of FIG. 4 In this example, the calibration circuit (the implementation of circuit 10) includes a switch 57 between circuit path 59 and the input terminal 60 of differential amplifier 61. Input terminal 62 of differential amplifier 61 is electrically connected to circuit path 59 without an intervening switch. The calibration circuit also includes a switch 64 between input terminals 60 and 62 of differential amplifier 61. Controlling the switches via a controller such as that described above, and in the manner described above with respect to FIGS. 1 to 3, allows the calibration circuit to provide an error signal corresponding errors that occur as a result of thermal (or other environmental) variations and common mode voltage variations in circuit path 59. As described above, the error signal may be used to program the input current to circuit path 59 to compensate for that error signal, and thereby compensate for errors in the operation of differential amplifier 67 that are caused by thermal variation and common mode voltage variation.

FIG. 4 also shows circuitry applying the concepts described herein to regulate forced voltage through a channel. For example, switches 82, 77 and 79 may be closed to measure voltage across the channel. To regulate that voltage, switch 82 may be open, thereby allowing for force voltage regulation accounting for, e.g., thermal and common mode variations in an amplifier 120 that measures that voltage across the channel.

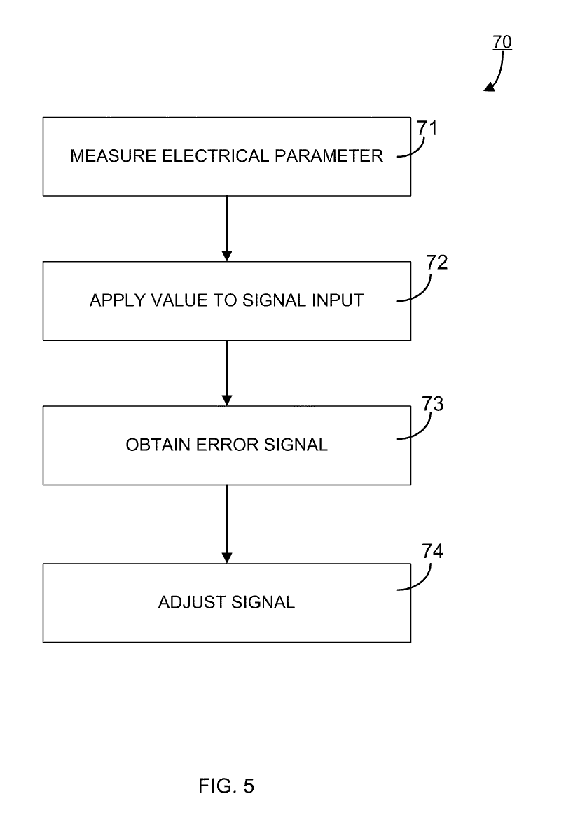

Referring to FIG. 5, a process 70 for compensating for errors includes measuring (71) an electrical parameter (e.g., voltage) across a circuit element (e.g., resistor 17) in a channel, and applying (72) a value corresponding to the electrical parameter to a signal input to the channel. Process 70 also includes obtaining (73) an error signal that corresponds to the electrical parameter, where the electrical parameter is measured by a first device (e.g., differential amplifier 19) and the error signal is obtained by a second device (e.g., differential amplifier 24). In this example, the first and second devices are of a same type. The error signal may be used to adjust (74) the signal (e.g., current) input to the channel.

Referring back to FIG. 4, the other elements in that circuit include switch 77 for high sense connection/disconnection, switch 78 for high force connection/disconnection, switch 79 for low sense connection/disconnection, switch 80 for connection/disconnection to a sub-calibration bus low, switch 81 for connection/disconnection to a sub-calibration bus high, switch 82 for connection/disconnection to a voltage measurement, and switch 83 for connection/disconnection to a voltage measurement correction. These switches are duplicated in both blocks 50 and 51.

Switch 78 connects circuit path 59 to a load, such as a battery (not shown) to be tested. The other switches and circuitry shown in FIG. 4 enable tests and measurements to be performed on the battery under test.

The foregoing describes circuit or channel-level calibration. A system-level (“in-situ”) calibration may be performed using a calibration tote. The system-level calibration may be performed to calibrate the test and formation bay of a battery test system with or without performing circuit-level calibration. An example of a battery test system in which the system-level calibration may be performed is described in U.S. patent application Ser. No. ______, entitled “REMOVING BAYS OF A TEST SYSTEM” (Attorney Docket No.: 18523-0120001/2231-US) filed concurrently herewith. The contents of U.S. patent application Ser. No. ______, entitled “REMOVING BAYS OF A TEST SYSTEM” (Attorney Docket No.: 18523-0120001/2231-US) are hereby incorporated by reference into this application as if set forth herein in full.

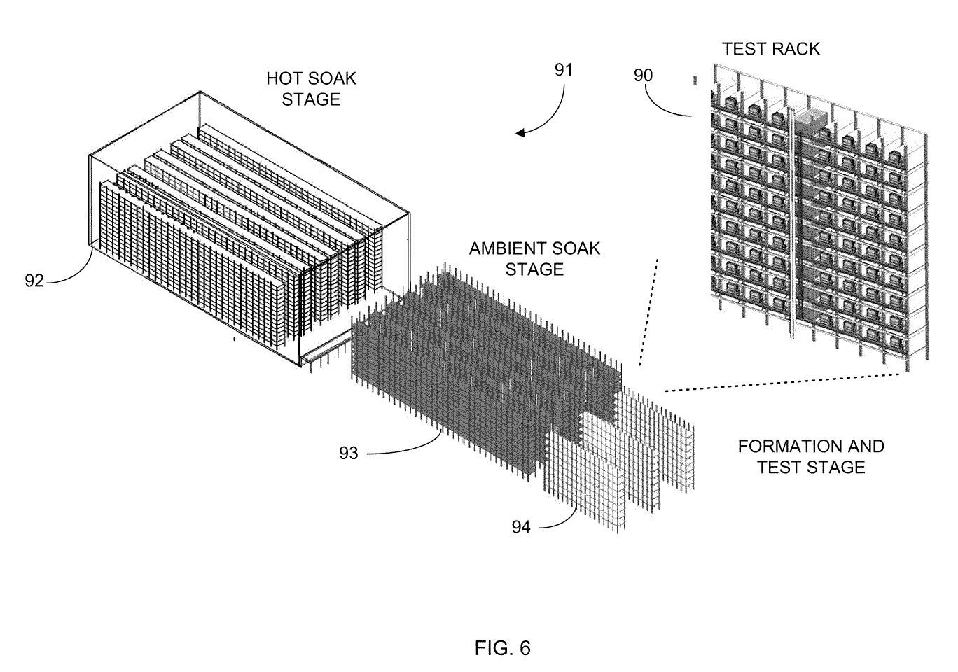

In this context, a tote is an apparatus for holding devices (e.g., batteries) to be tested by the system. A tote is inserted, by a robot, into a test and formation bay 90 of a test system 91, such as that shown in FIG. 6, which includes a hot soak stage 92, an ambient soak stage 93, and a formation and test stage 94. A calibration tote mimics an actual tote physically, at least in terms of its interface to the test channels, but has known (or determinable) electrical characteristics (e.g., resistance). The calibration tote may be connected in place of a battery under test, and may be used to calibrate a test channel in the manner described below. The calibration tote is movable among bays in order to calibrate all channels (or a subset thereof) of a bay. Battery formation and test being performed in other bays need not be interrupted while the bay with the calibration tote is undergoing a calibration process.

The overall calibration process is directed by a host computer (not shown). Individual measurements performed by a calibration meter and channels undergoing calibration are passed back to the host computer, where mathematical process(es) for generating calibration factors occur. Once the calibration factors are generated by the host computer, they are downloaded to a test channel board in the bay. The calibration factors are applied to the channel by the channel board control logic.

In this implementation, the calibration tote has the same form factor as that of a tote containing cells undergoing formation. One or more calibration totes will normally reside within the ambient formation racks. When a test bay is scheduled to be calibrated, the formation host will direct a robot to convey a calibration tote to the bay to be calibrated. For each instance of test bay calibration performed, the identity (e.g., serial number) of the calibration tote used to perform that calibration will be recorded by the host computer.

In one implementation, the calibration tote includes an array of low drift precision resistors, e.g., one resistor for every two formation channels. Each resistor may be calibrated externally prior to entering the battery test and formation system and its characteristics will be loaded to the formation host software during system boot up. It may be necessary to recalibrate the calibration tote's transfer standards at some interval in order to maintain accuracy specifications. In the event of a calibration tote recalibration, the calibration tote will leave the system for calibration and, upon reentry, an operator will enter its identifier (e.g., serial number), calibrated reference value(s), and calibration date of the tote.

A channel undergoing calibration need not be aware of the calibrated value of resistors in the calibration tote, since the mathematical processes used to generate calibration factors are executed by the host computer.

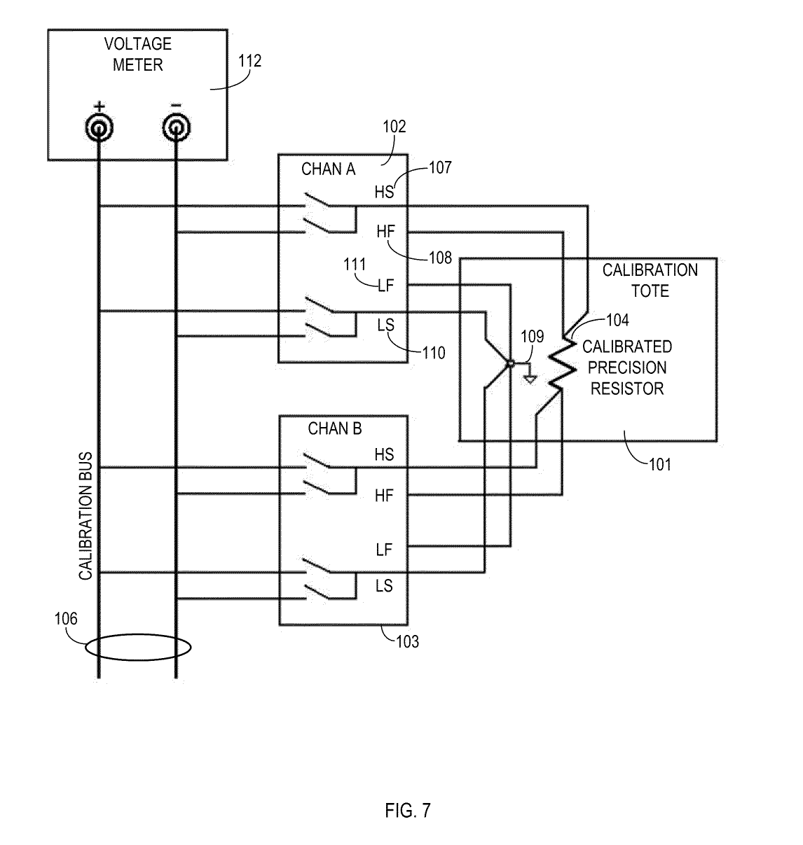

FIG. 7 shows an example of a calibration tote 101. As shown in FIG. 7, calibration tote 101 is connectable to multiple channels 102, 103 of a bay. The calibration tote includes a resistor 104. For each channel, resistor 104 is electrically connectable to a calibration bus 106 via a high sense (HS) switch 107 or a high force (HF) switch 108. In this context, “force” refers to an electrical path for forcing a current or voltage and “sense” refers to an electrical path for sensing a current or voltage. In each channel, calibration bus 106 is electrically connectable to a reference voltage 109, such as ground, via a low sense (LS) switch 110 or a low force (LF) switch 111. Calibration bus 106 is electrically connected to a meter 112 for obtaining measurements using the calibration tote, as described below.

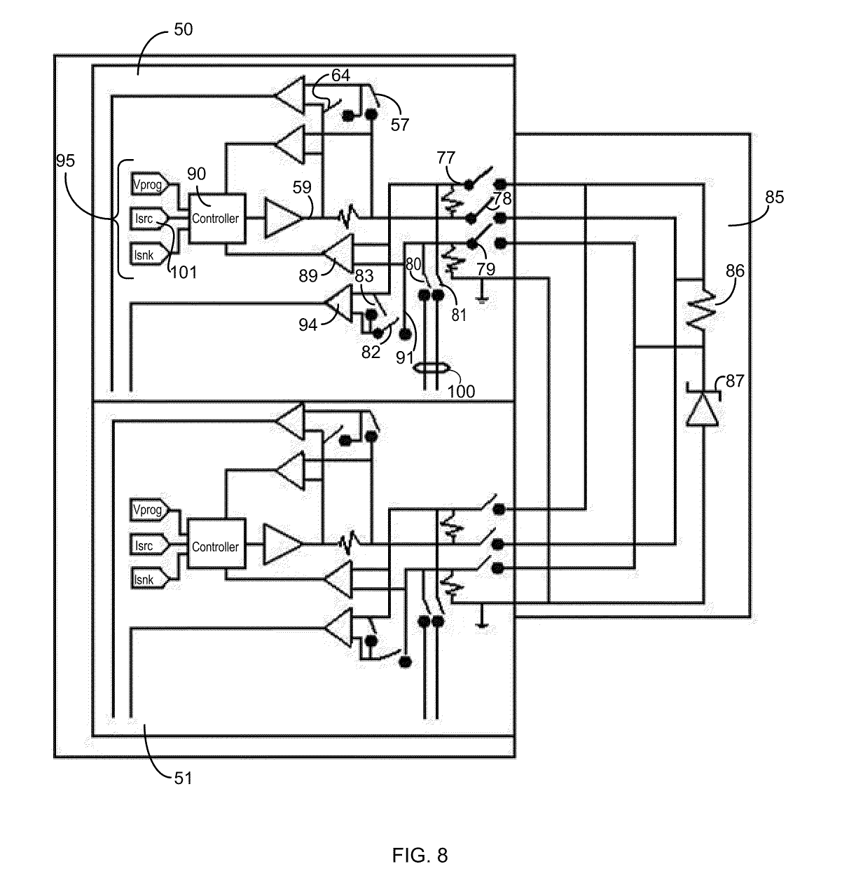

In the example of FIG. 8, calibration tote 85 includes a resistor 86 and a Zener diode 87. Channels 50 and 51 are connectable to the calibration tote, as shown in FIG. 8, and to a calibration bus 100. The calibration bus 100 transmits calibration signals from the channels, to one or more meters (e.g., voltage meters, ammeters—not shown), which are connected to a computer (not shown) controlling the testing.

Examples of test procedures using the calibration tote of FIG. 8 are as follows. The value of resistor 86 is associated with a serial number of the calibration tote, and is stored in a database. During testing, the calibration tote may be attached to channels (e.g., two channels) of the channel board, as shown in FIG. 8, and the serial number is scanned so that the value of the reference resistor on the calibration tote can be obtained from the database. This value is provided to the computer controlling the testing, and may be used in generating calibration factors. The calibration factors may be used to configure an apparatus, such as a digital signal processor (DSP), to generate digital signals that corresponds to test signals. In particular, the calibration factors may be used to program the DSP to output digital signals that are adjusted for errors identified during calibration.

To perform voltage force and meter calibration, a precision voltage measuring instrument (see FIG. 7) (e.g., a voltage meter), is connected to calibration bus 100 The following actions are then performed. Switches 80 and 81 are closed; switches 77, 78 and 79 are opened (thereby disconnecting the calibration tote from the channel); and switch 82 is closed and switch 83 is opened. Channels that are not being calibrated—in this case, channel 51—are then disabled via their switches. The channel under calibration—in this case, channel 50—is soft kelvined at its sense lines, and the meter is connected across the sense lines. Voltages across a range may then be forced to the channel under calibration. At each voltage point, a reading is taken with the meter and a channel voltmeter connected to the calibration bus. A transfer curve may then be determined between the meter readings and forced voltages and between the meter readings and channel voltmeter readings. Channel calibration factors (e.g., gain an offset) can be generated for forcing and metering and stored in memory. These calibration factors may be applied to calibrate the channel. This procedure may be repeated for all channels in a bay.

To perform current force and meter calibration, a precision voltage measuring instrument, is connected to calibration bus 100. The following actions are then performed. Switches 80 and 81 are closed; switches 77, 78 and 79 are closed (thereby connecting the calibration tote to channel 50, and its resistor 86, to the channel); switch 57 is opened; and switch 64 is closed. Channels that are not being calibrated—in this case, channel 51—are then disabled via their switches. A current source (Isrc 101), controls the current output to the channel. The meter leads are connected across resistor 86 via switches 80 and 81. Current points across a range are then forced through the channel. At each current point, the meter will make a voltage measurement across resistor 86, and a channel ammeter (not shown) will also make a current measurement. Calibration factors for the channel (e.g., gain and offset) can then be generated and stored in memory. These calibration factors may be applied to calibrate the channel. This procedure may be repeated for all channels in a bay.

The circuitry and process shown in FIGS. 1 to 8 may be used in any type of test system. In one example, the circuitry is incorporated into a battery test system, such as the battery test system described in U.S. patent application Ser. No. ______, entitled “REMOVING BAYS OF A TEST SYSTEM” (Attorney Docket No.: 18523-0120001/2231-US) filed concurrently herewith.

Testing of batteries may be controlled by a computer (not shown), e.g., by sending signals to and from one or more of the foregoing connections. The testing may be performed using hardware or a combination of hardware and software. In this regard, any of the testing performed by the system described herein can be implemented, at least in part, via a computer program product, e.g., a computer program tangibly embodied in an information carrier, such as one or more machine-readable media, for execution by, or to control the operation of, one or more data processing apparatus, e.g., a programmable processor, a computer, multiple computers, and/or programmable logic components.

A computer program can be written in any form of programming language, including compiled or interpreted languages, and it can be deployed in any form, including as a stand-alone program or as a module, component, subroutine, or other unit suitable for use in a computing environment. A computer program can be deployed to be executed on one computer or on multiple computers at one site or distributed across multiple sites and interconnected by a network.

Actions associated with implementing all or part of the functions can be performed by one or more programmable processors executing one or more computer programs to perform the functions of the calibration process. All or part of the functions can be implemented as, special purpose logic circuitry, e.g., an FPGA and/or an ASIC (application-specific integrated circuit).

Processors suitable for the execution of a computer program include, by way of example, both general and special purpose microprocessors, and any one or more processors of any kind of digital computer. Generally, a processor will receive instructions and data from a read-only memory or a random access memory or both. Components of a computer include a processor for executing instructions and one or more memory devices for storing instructions and data.

Components of different implementations described herein may be combined to form other implementations not specifically set forth above. Components may be left out of the structures described herein, or changed, without adversely affecting their operation. Furthermore, various separate components may be combined into one or more individual components to perform the functions described herein.

Although the test system described herein tests electrochemical storage cells (e.g., batteries), that test system may be used to test any type of device.

The calibration tote is not limited to the structures shown in FIGS. 7 and 8. Rather, any calibration circuit with an impedance may be used.

The term “electrical connection” used herein may imply a direct physical connection or a connection that includes intervening components but that nevertheless allows electrical signals to flow between connected components. Any “connection” described herein, unless stated otherwise, is an electrical connection and not necessarily a direct physical connection regardless of whether the word “electrical” is used to modify “connection”.

The circuitry described herein is not limited to use with a battery test system or to the architecture shown (e.g., FIG. 6). Rather, the circuitry can be used with any type of test system to test any type of device.

The features described herein may be combined with any one or more of the features described in the following applications: U.S. Provisional Application No. ______, entitled “TEST SYSTEM” (Attorney Docket No. 18523-100P01/2236-US); U.S. patent application Ser. No. ______, entitled “ELECTRONIC DETECTION OF SIGNATURES” (Attorney Docket No. 18523-0119001/2234 US); U.S. patent application Ser. No. ______, entitled “REMOVING BAYS OF A TEST SYSTEM” (Attorney Docket No. 18523-0120001/2231-US); U.S. patent application Ser. No. ______, entitled “CALIBRATING A CHANNEL OF A TEST SYSTEM” (Attorney Docket No. 18523-0121001/2232-US); and U.S. patent application Ser. No. ______, entitled “ZERO INSERTION FORCE SCRUBBING CONTACT” (Attorney Docket No. 18523-0122001/2233-US). The contents of the following applications are incorporated herein by reference if set forth herein in full: U.S. Provisional Application No. ______, entitled “TEST SYSTEM” (Attorney Docket No. 18523-100P01/2236-US); U.S. patent application Ser. No. ______, entitled “ELECTRONIC DETECTION OF SIGNATURES” (Attorney Docket No. 18523-0119001/2234 US); U.S. patent application Ser. No. ______, entitled “REMOVING BAYS OF A TEST SYSTEM” (Attorney Docket No. 18523-0120001/2231-US); U.S. patent application Ser. No. ______, entitled “CALIBRATING A CHANNEL OF A TEST SYSTEM” (Attorney Docket No. 18523-0121001/2232-US); and U.S. patent application Ser. No. ______, entitled “ZERO INSERTION FORCE SCRUBBING CONTACT” (Attorney Docket No. 18523-0122001/2233-US).

Other embodiments not specifically described herein are also within the scope of the following claims.

What is claimed is:

1. Circuitry comprising:
a circuit path that corresponds to a channel of system for testing a device;
an element in the circuit path;
a first device to measure an electrical parameter associated with the element;
a second device to obtain an error signal associated with the channel; and
a feedback path electrically connected to the second device to pass the error signal or another signal.

2. The circuitry of claim 1, wherein the second device is configurable for operation in different modes, wherein, in a first of the modes, the second device is configured to obtain the error signal, and, in a second of the modes, the second device is configured to measure the electrical parameter and the feedback path is configured to pass the other signal, the other signal corresponding to the electrical parameter.

3. The circuitry of claim 2, wherein configuration of the second device is performed by controlling switches electrically connected to inputs of the second device.

4. The circuitry of claim 1, wherein the circuitry further comprises:
a controller to receive the error signal and to adjust an amount of current output to the current path in accordance with the error signal.

5. The circuitry of claim 1, wherein the error signal corresponds to a variation in voltage caused by thermal drift and variations in common mode voltage in the channel.

6. The circuitry of claim 1, wherein the first device comprises input terminals, with an input terminal electrically connected at each end of the element;
wherein the second device comprises input terminals; and
wherein the circuitry further comprises:
at least one switch.

7. The circuitry of claim 5, wherein the at least one switch comprises:
a first switch between a first input terminal of the second device and a first end of the element; and
a second switch between a second input terminal of the second device and the first input terminal of the second device.

8. The circuitry of claim 7, further comprising control circuitry to:
control the first switch to open, thereby disconnecting the first input terminal from the first end of the electrical element, and
control the second switch to close, thereby electrically connecting the first input terminal to the second input terminal, the second input terminal being electrically connected to a second end of the element.

9. The circuitry of claim 1, further comprising:
a second feedback path electrically connected to the first device for compensating the input signal based on the electrical parameter measured at the first device.

10. The circuitry of claim 1, wherein the first device comprises a differential amplifier connected across the element; and
wherein the second device comprises a differential amplifier comprising inputs that are electrically connectable to each other and that are electrically connectable across the element.

11. The circuitry of claim 1, wherein the element comprises a resistor and the electrical parameter comprises a voltage associated with a current through the resistor.

12. The circuitry of claim 1, wherein the second device is configured to generate an analog signal that corresponds to the electrical parameter associated with the element; and
wherein the circuitry further comprises:
a controller to produce a digital signal; and
an analog-to-digital converter to produce a digitized version of the analog signal, the digitized version of the analog signal being provided to the controller.

13. The circuitry of claim 11, wherein the controller is configured to alter the digital signal in accordance with the digitized version of the analog signal.

14. The circuitry of claim 1, wherein the device comprises a battery.

15. Circuitry for use in a system comprised of bays for testing devices, the circuitry comprising:
a circuit path to pass a test signal;
a calibration tote electrically connected to the circuit path; and
a measurement device to determine an electrical parameter associated with the calibration tote in response to the test signal;
wherein the calibration tote is usable without interrupting testing of devices in other bays of the system.

16. The circuitry of claim 15, further comprising:
an apparatus configured to alter the test signal based on the electrical parameter.

17. The circuitry of claim 16, wherein the apparatus comprises a digital signal processor (DSP) that is configured to generate a digital signal that corresponds to the test signal, the DSP altering the digital signal to alter the test signal.

18. The circuitry of claim 15, wherein the calibration tote comprise a resistor in series with a Zener diode, and the electrical parameter comprises a voltage measured at least across the resistor.

19. The circuitry of claim 15, wherein the calibration tote is movable among bays in the system.

20. The circuitry of claim 13, wherein the devices comprise batteries.

21. A method of calibrating a channel of a device test system during operation of the device test system, the method comprising:
measuring an electrical parameter across a circuit element in the channel;
applying a value corresponding to the electrical parameter to a signal input to the channel; and
obtaining an error signal associated with the channel, the electrical parameter being measured by a first device and the error signal being measured by a second device.

22. The method of claim 21, further comprising:
using the error signal to adjust the signal input to the channel.

23. The method of claim 22, wherein using the error to adjust the signal input to the channel comprises programming a controller to alter the signal in accordance with the error signal.

24. The method of claim 21, wherein the signal is adjusted in real-time during testing of a device by the device test system.

25. The method of claim 21, wherein obtaining the error signal comprises electrically disconnecting a first terminal of the second device from a circuit path corresponding to the channel and electrically connecting first and second terminals of the second device to each other.

26. The method of claim 25, wherein electrically disconnecting and electrically connecting are performed by electrically-controllable switches.

27. The method of claim 21, wherein the channel of the device test system is part of a bay of a test rack; and
wherein the method further comprises calibrating all channels of the bay using a calibration tote.

28. A method of calibrating a bay of a test system, comprising:
moving a calibration tote into the bay; and
performing calibration on the bay using the calibration tote, the calibration being performed without interrupting processes being performed on devices in other bays.

29. The method of claim 28, wherein the calibration tote comprises a resistor; and
wherein performing calibration comprises obtaining an electrical parameter by measuring a value associated with the resistor.

30. The method of claim 29, wherein performing calibration further comprises:
determining a calibration factor for the bay using the value associated with the resistor.
